(19) United States
(12) Patent Application Publication
(10) Pub. No.: US 2015/0315070 A1
(43) Pub. Date: Nov. 5, 2015

(54) TRANSPARENT SUBSTRATE, IN PARTICULAR A GLASS SUBSTRATE, COATED WITH AT LEAST ONE AT LEAST BIFUNCTIONAL POROUS LAYER, MANUFACTURING METHOD AND USES THEREOF

(71) Applicants: SAINT-GOBAIN GLASS FRANCE, Courbevoie (FR); CENTRE NATIONAL DE LA RECHERCHE SCIENTIFIQUE, Paris Cedex 16 (FR)

(72) Inventors: Anouchka BENAKLI, Orsay (FR); Elodie BOURGEAT-LAMI, Nievroz (FR); François GUILLEMOT, Paris (FR)

(21) Appl. No.: 14/650,113

(22) PCT Filed: Dec. 20, 2013
(86) PCT No.: PCT/FR2013/053219

§ 371 Date: Jun. 5, 2015

(30) Foreign Application Priority Data
Dec. 28, 2012 (FR) 1262959

(51) Int. Cl. C03C 17/00; C03C 17/34; B05D 5/06; B05D 3/00; B05D 1/00; C03C 17/245; H01L 31/048

(52) U.S. Cl. CPC C03C 17/007; C03C 17/002; C03C 17/2456; C03C 17/3417; H01L 31/0481; B05D 3/007; B05D 1/005; B05D 5/06; C03C 2217/425; C03C 2217/45; C03C 2217/477; C03C 2217/48; C03C 2217/73; C03C 2218/113; C03C 2218/154

(57) ABSTRACT

A transparent glass or ceramic or glass-ceramic substrate, coated with a functional layer or with a stack of at least two functional layers, the functional layer or at least one of the functional layers of the stack being porous and made of an inorganic material M1, wherein the or at least one of the porous functional layer(s) of inorganic material M1 has, at the surface of at least one portion of the pores thereof, at least one inorganic material M2 different from M1.

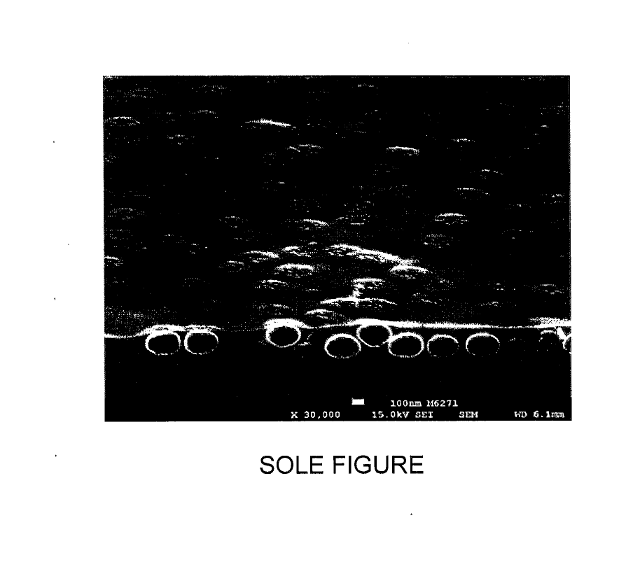

The present invention relates to a transparent substrate, in particular a glass substrate, coated with at least one at least bifunctional porous layer, to a process for manufacturing said coated substrate and to the use thereof as element of an optoelectronic device or of a glazing unit.

Glazing units intended for the photovoltaic market are known that are coated with a layer having a low refractive index (antireflection layer) deposited by a liquid method. This layer is produced according to the sol-gel process with the aid of a silica precursor and organic nanoparticles (latex). This porous layer, prepared in this way, has the advantage of being inexpensive and of having the very good antireflection optical performance desired and also a stability of these performances with respect to the environment (humidity of the air, pollution).

International PCT application WO 2008/059170 A2 describes the formation of such an essentially mineral porous layer of sol-gel type, having a series of closed pores.

French patent application 2 974 800 A1 describes a transparent substrate coated with a stack of layers, a porous layer of which is covered with at least one other layer. The layers of this stack are selected for their specific optical and mechanical properties. For example, use is made of layers having a variable refractive index in order to create a refractive index gradient.

The supports coated with at least one porous layer from the prior art are entirely satisfactory. However, it has emerged that they could be improved due to various observations:
the known porous layers have the sole function of being antireflective; for example, if the substrate coated with such an antireflection porous layer is used as cover glass for a photovoltaic panel, it may readily become fouled; adding value to the glasses and glazing units thus coated with an antireflection coating could therefore be achieved through the addition of a second function to the core of the layer, in particular a self-cleaning or “easy-to-clean” function; in the aforementioned case of the cover glass, reduced fouling would make it possible to improve the energy functions of the module;
porous silica layers are degraded during hydrolytic ageing of the layer; in particular, the corrosion of the glass substrate may give rise to a solubilization of the silica layer, which may precipitate again in the form of a not very dense silica gel layer; the addition of another material to the surface of the pores could provide a solution to this problem;
the mechanical properties of porous materials are intrinsically worse than those of a dense material; this is demonstrated for an antireflection porous layer by a relatively low scratch resistance; the addition of another dense material within a porous silica layer could improve the mechanical properties thereof.

The Applicant company has sought a solution that makes it possible to respond to all of the problems mentioned above in order to propose an at least bifunctional porous layer, comprising, in addition to the functionality of the porous layer as such, at least one other functionality, which may be of any type, which makes it possible to propose substrates having various properties, which are advantageously adjustable and which offer the additional advantage of making it possible to construct stacks of layers with various properties that are adjusted depending on the application in question.

For this purpose, according to the invention, it is proposed to carry out the functionalization of the surface of pores by the use of a nanocomposite latex (sometimes referred to hereinbelow as composite latex). Such a latex is in the form of a dispersion of organic nanoparticles that are surface-coated with an inorganic material, in particular with inorganic particles, which may be physisorbed (electrostatic interaction for example) or chemisorbed at the surface of the polymer particles (strong bond between the inorganic material and the polymer), such a particle morphology is sometimes referred to as “raspberry morphology”.

An additional advantage of such an approach is that the pores are not filled with a second material, which here is deposited only at the surface of the pores. Thus, when this second material is expensive or has optical properties that will limit the antireflection effect, the amount thereof within the layer is minimized while benefiting from its surface properties.

A first subject of the present invention is therefore a transparent glass or ceramic or glass-ceramic substrate, coated with a functional layer or with a stack of at least two functional layers, said functional layer or at least one of said functional layers of the stack being porous and made of an inorganic material M1, characterized in that the or at least one of the porous functional layer(s) of inorganic material M1 has, at the surface of at least one portion of the pores thereof, at least one inorganic material M2 different from M1.

The expression “inorganic material M2 different from M1” encompasses materials of the same chemical nature but which may be in different physical forms, such as a less dense silica and a more dense silica.

The inorganic material M2 is advantageously present at the surface of all the pores of a porous layer of inorganic material M1.

The inorganic material M1 may advantageously be a material that results from the curing of a sol-gel solution of at least one metal oxide precursor and/or of at least one organosilane of general formula:

RₙSiX₄₋ₙ,

wherein:
n is equal to 0, 1, 2 or 3, preferably is equal to 0 or 1;
the X groups, which may be identical or different when n is equal to 0, 1 or 2, represent hydrolyzable groups selected from alkoxy, acyloxy or halide groups, preferably alkoxy groups; and
the R groups, which may be identical or different when n is equal to 2 or 3, represent non-hydrolyzable organic groups or organic functions bonded to the silicon via a carbon atom,
   said metal oxide precursor(s) and said organosilane(s) having undergone a hydrolysis and a condensation during said curing.

In particular, a metal oxide precursor may be a precursor of an oxide of a metal selected from Si, Ti, Zr, Al, Zn, Sn, Nb, Sb.

The X groups may advantageously be selected from —O—R′ alkoxy groups, with R′ representing a C₁-C₄ alkyl group, in particular methoxy or ethoxy groups, —O—C(O)R″ acyloxy groups, with R″ representing an alkyl radical, such as a C₁-C₆ alkyl, in particular methyl or ethyl; halides such as Cl, Br and I; and combinations thereof.

The R groups may advantageously be selected from methyl, glycidyl or glycidoxypropyl groups.

The pores may for example represent 5% to 74% by volume of a porous layer of inorganic material M1.

The pores of a porous layer may be of spherical or ovoid shape.

The inorganic material M2 may advantageously be in the form of nanoparticles adsorbed at the surface of the pores of the inorganic material M1.

The inorganic material M2 may also be in the form of a shell over the entire inner surface of the pores.

The inorganic material M2 is advantageously derived from an inorganic phase that can be dispersed in the form of nanoparticles in water and that can be adsorbed at the surface of particles of a latex, referred to as base latex, in particular by heterocoagulation and advantageously with ultrasonic agitation.

The nanoparticles of the material M2 may be Catalytic nanoparticles, such as photocatalytic and thermocatalytic nanoparticles, or luminescent particles.

The material M2 may be based on at least one metal oxide, such as an oxide of Si, Ti, Zr, Al, Zn, Sn, Nb, Sb, Ce, or on a vanadate containing lanthanide ions.

The layer of material M1 may have a thickness of from 50 nm to 5 μm, preferably from 100 nm to 2 μm and that the pores that it contains have a mean largest dimension of from 30 to 600 nm.

In the case of nanoparticles adsorbed at the surface of the pores of the material M1, these may have a dimension of from 5 to 100 nm.

In the case where the inorganic material M2 is in the form of a shell over the entire inner surface of the pores, this shell may have a thickness of from 2 to 50 nm.

In accordance with one more particular embodiment, the material M1 is derived from a hydrolyzed SiO₂ precursor and the material M2 is TiO₂, the porous layer being an antireflection layer with a low refractive index and that has a self-cleaning functionality.

In one particular embodiment, the coated substrate according to the invention comprises a stack of functional layers of which the porous functional layer(s) of inorganic material M1 having, at the surface of at least one portion of the pores thereof, at least one inorganic material M2 different from M1 are part, the functional layer(s) other than the aforementioned porous functional layer(s) having been deposited by a liquid method or by sputtering, such as PVD, CVD, or by liquid pyrolysis.

The present invention also relates to a process for manufacturing a coated substrate as defined above, characterized in that, deposited by a liquid method on a glass or ceramic or glass-ceramic substrate is at least one layer of an aqueous mixture of inorganic material M1 precursor and of a composite aqueous latex, the particles of which each consist of an organic core having a material M2 at the surface, and that heating is applied until the organic cores and water present in the mixture of precursor and of composite latex are eliminated or substantially eliminated.

Use is advantageously made, as inorganic material M1 precursor, of a sol-gel solution of at least one metal oxide precursor and/or of at least one organosilane of general formula:

RₙSiX₄₋ₙ,

wherein:
n is equal to 0, 1, 2 or 3, preferably is equal to 0 or 1;
the X groups, which may be identical or different when n is equal to 0, 1 or 2, represent hydrolyzable groups selected from alkoxy, acyloxy or halide groups, preferably alkoxy groups; and
the R groups, which may be identical or different when n is equal to 2 or 3, represent non-hydrolyzable organic groups or organic functions bonded to the silicon via a carbon atom,
   the inorganic material M1 being obtained by curing said sol-gel solution, during which said metal oxide precursor(s) and said organosilane(s) undergo a hydrolysis and a condensation.

A metal oxide precursor may be a precursor of an oxide of a metal selected from Si, Ti, Zr, Al, Zn, Sn, Nb, Sb.

The X groups may be selected from —O—R′ alkoxy groups, with R′ representing a C₁-C₄ alkyl group, in particular methoxy or ethoxy groups, —O—C(O)R″ acyloxy groups, with R″ representing an alkyl radical, such as a C₁-C₆ alkyl, in particular methyl or ethyl; halides such as Cl, Br and I; and combinations thereof.

The R groups may be selected from methyl, glycidyl or glycidoxypropyl groups.

In one particular embodiment, use is made of tetraethoxysilane (TEOS) as inorganic material M1 precursor.

In accordance with one particularly advantageous embodiment, the composite aqueous latex is prepared by mixing a base latex obtained by aqueous emulsion polymerization of a polymer or copolymer P with a dispersion in water of nanoparticles of organic material M2 under heterocoagulation conditions, and advantageously with ultrasonic agitation, in order to obtain a nanocomposite latex, of which the polymer or copolymer P particles constituting said organic cores bear at the surface said nanoparticles of material M2.

The heterocoagulation and the ultrasonic agitation result in a stable dispersion of the polymer particles coated with nanoparticles.

In the case where the inorganic material M2 is in the form of a shell over the entire inner surface of the pores of a porous layer, the composite aqueous latex may be prepared by mixing a base latex obtained by aqueous emulsion polymerization of a polymer or copolymer P with an inorganic material M2 precursor in solution, and by adjusting the reaction conditions so that a condensation reaction takes place over the entire surface of the Particles of the base latex, forming a covering of said particles with the inorganic material M2.

The polymer or copolymer P may be selected from poly(methyl methacrylate), methyl methacrylate/butyl acrylate copolymers and polystyrene.

Use may advantageously be made of a material M2 based on at least one metal oxide such as an oxide of Si, Ti, Zr, Al, Zn, Sn, Nb, Sb, Ce, or on a vanadate containing lanthanide ions.

The layer of mixture may be deposited by spin coating.

In order to form a stack of layers, at least one other functional layer is advantageously deposited by a liquid method or by sputtering, such as PVD, CVD, or by liquid pyrolysis, in the order desired for the stack of layers.

Another subject of the present invention is the use of the coated substrate as defined above or manufactured by the process as defined above as an element of an optoelectronic device, such as photovoltaic module and light-emitting device, or of a single or multiple, monolithic or laminated glazing unit for buildings and transport vehicles.

Another subject of the present invention is a photovoltaic module comprising a coated substrate as defined above or manufactured by the process as defined above as cover glass.

Another subject of the present invention is a light-emitting device comprising a coated substrate as defined above or manufactured by the process as defined above as an organic light-emitting diode (OLED).

Another subject of the present invention is a single or multiple, monolithic or laminated glazing unit for buildings and transport vehicles, comprising at least one coated substrate as defined above or manufactured by the process as defined above as pane or sheet of glass of a multiple glazing unit.

The following examples illustrate the present invention without however limiting the scope thereof.

### EXAMPLE 1

### Preparation of a Hydrolyzed Silica Precursor Sol (Refer to as Silica Sol)

Introduced into a round-bottomed flask were 14.2 ml (nSi=numbers of moles of silica precursor=6.4×10⁻² mol) of tetraethoxysilane (TEOS), 11.2 ml of ethanol (3nSi mol of ethanol) and 4.62 ml of a solution of hydrochloric acid in deionized water, the pH of which is equal to 2.5 (4nSi mol of water). The mixture was brought to 60° C. for 60 min with stirring. The objective was then to prepare a solution containing the silica precursor at a concentration of 2.90 mol/1 in water, by having eliminated as much ethanol as possible. In order to obtain the desired concentration, the final volume of solution had to be 22 ml.

After the first step, the sol contained 7nSi mol of ethanol (initial ethanol, plus ethanol released by hydrolysis), which corresponded to a volume of 26 ml (the density of ethanol is equal to 0.79).

Added to the sol resulting from the first step were 20 ml of hydrochloric acid solution, the pH of which is equal to 2.5. The mixture was placed under vacuum and heated gently in a rotary evaporator in order to remove the ethanol therefrom.

After this step, the volume of solution was brought to 22 ml with addition of the hydrochloric acid solution, the pH of which is equal to 2.5 and the silica sol was ready.

### EXAMPLE 2

### Preparation of a Base Latex

Introduced into a 500 ml jacketed reactor, thermostatically controlled at 70° C., equipped with a mechanical stirrer, a condenser and an inlet for nitrogen bubbling were 151 g of deionized water (resistivity >16 M) and two surfactants: 0.45 g of TERGITOL™ NP-30 (Dow Chemical) and 0.02 g of sodium dodecyl sulfate.

At the same time, the monomers: 24 g of methyl methacrylate (MMA, 99%, Aldrich) and 6.1 g of butyl acrylate (ABu, Aldrich), on the one hand, and the initiator: 0.3 g of sodium persulfate diluted in a small amount of water (withdrawn from the 151 g), on the other hand, were placed in separate flasks equipped with folding skirt stoppers.

The contents of the reactor and also that of the two flasks were deaerated for 15 min by nitrogen bubbling.

The monomers and the polymerization initiator were then introduced in one go into the reactor under mechanical stirring (250 rpm). The entire reaction was carried out in a sealed reactor, with the stream of nitrogen maintained just above the reaction medium. The reaction medium became cloudy rapidly after the addition of the monomers due to the formation of monomer droplets. After a few minutes, the medium took on a white coloring, a sign of light scattering by the particles already formed. The polymerization was continued for two hours, and the reactor was drained. The conversion achieved was 99.1%.

The latex was characterized by dynamic light scattering (Particle size analysis—Photon correlation spectroscopy 13321:1996, International Standards Organization) and measurement of the zeta potential on a ZetaSizer machine sold by Malvern. Thus, the mean diameter of the objects measured is 230 nm and the polydispersity index is equal to 0.016. The zeta potential is measured at −31.8 mV.

### EXAMPLE 3

### Preparation of a Nanocomposite Latex by Heterocoagulation

Added to 10 g of the latex prepared previously and placed in an ultrasonic bath were TiO₂ nanoparticles by addition of 5.7 g of an aqueous dispersion of these nanoparticles.

The dispersion of the TiO₂ particles used was the product sold by Cristal Global under the reference SA-300A corresponding to a stable aqueous dispersion of TiO₂ particles at a concentration of 23% by weight relative to the total weight of the dispersion, having a BET specific surface area of around 330 m²/g and a mean diameter of the order of 50 nm.

The use of an ultrasonic bath made it possible to limit the flocculation phenomenon observed when a drop of TiO₂ nanoparticles is added to the latex suspension. This immediate destabilization is linked to a very strong electrostatic interaction between the TiO₂ particles and the polymer particles.

### EXAMPLES 4A TO 4D

### Preparation of the Silica Sol from Example 1—Nanocomposite Latex from Example 3 Mixtures

Four mixtures of the silica sol from Example 1 with the nanocomposite latex from Example 3 were produced in the proportions indicated in Table 1 below.

TABLE 1

Example

| | 4A | 4B | 4C | 4D |
|---|---|---|---|---|
| Mass of silica sol | 1.79 | 1.61 | 1.44 | 1.25 |
| (g) | | | | |
| Mass of | 0.16 | 0.32 | 0.49 | 0.66 |
| nanocomposite latex | | | | |
| (g) | | | | |
| Mass of HCl | 0.06 | 0.07 | 0.08 | 0.09 |
| solution at pH = 2 (g) | | | | |
| Porosity (%) | 10 | 20 | 30 | 40 |

### EXAMPLES 5A TO 5D

### Formation of the Porous Layers According to the Invention

Using a Pasteur pipette, each of the mixtures of Examples 4A to 4D were deposited over the entire surface of a glass plate fixed to a rotatable horizontal support and the support was rotated at 2000 rpm for 60 s until a uniform layer was obtained (spin-coating technique).

Each of the layers was then calcined at 450° C. for one and a half hours.

Scanning electron microscopy (SEM) images of the porous layers were taken and the desired morphology for the pores carpeted in TiO₂ nanoparticles was observed in these images. The sole FIGURE of the appended drawing shows an SEM image of the porous layer corresponding to Example 5C.

The refractive index was measured at 600 nm for each of these layers via ellipsometry and their reflectivity was measured at 600 nm via UV-visible spectroscopy.

The results are reported in Table 2 below.

TABLE 2

Layer of Example

| | 5A | 5B | 5C | 5D |
|---|---|---|---|---|
| Refractive | 1.430 | 1.395 | 1.378 | 1.345 |
| index at | | | | |
| 600 nm | | | | |
| Reflectivity | NA | 5% | 4% | 3% |
| at 600 nm | | | | |

It is noted that the reflectivity of the coated substrates may be lower than that of the base glass (4%).

The graph for measuring the refractive index that may be plotted as a function of the porosities using the porosities given in Table 1 and the refractive indices given in Table 2 shows a straight line, thereby indicating that it is simple to adjust the refractive index and showing the conformity with Brüggeman's effective medium model.

### EXAMPLE 6

### Photocatalytic Test

In order to evaluate the photocatalytic activity of the porous layers under UV-A light, a stearic acid photodegradation test was carried out.

This test consists in depositing a certain amount of stearic acid on the layers by spin coating, which stearic acid is used as a pollutant of the layer, then in monitoring the change in its concentration, via transmission IR spectroscopy, and after deposition, then during exposure to UV light in the range 315-400 nm.

The transmission infrared spectrum is reprocessed by subtracting the spectrum of the sample obtained before deposition of the stearic acid. Subsequently, the absorbance spectrum is obtained from the inverse of the transmittance spectrum, centered about the region 2825-2950 cm⁻¹. A decrease in the intensity of the bands of characteristic vibrations of stearic acid is observed on the absorption spectrum as the sample is exposed to UV-A light.

With this test, the layer of Example 5A degraded 18% of the deposited amount of stearic acid under UV-A radiation over 150 min.

1. A transparent glass or ceramic or glass-ceramic substrate, coated with a functional layer or with a stack of at least two functional layers, said functional layer or at least one of said functional layers of the stack being porous and made of an inorganic material M1, wherein the porous functional layer of inorganic material M1 or the at least one porous functional layer, of the stack of at least two functional layers, of inorganic material M1 has, at a surface of at least one portion of the pores thereof, at least one inorganic material M2 different from M1.

2. The coated substrate as claimed in claim 1, wherein the inorganic material M2 is present at the surface of all the pores of a porous layer of inorganic material M1.

3. The coated substrate as claimed in claim 1, wherein the inorganic material M1 is a material that results from the curing of a sol-gel solution of at least one metal oxide precursor and/or of at least one organosilane of general formula:
RₙSiX₄₋ₙ,
wherein:
n is equal to 0, 1, 2 or 3,
the X groups, which may be identical or different when n is equal to 0, 1 or 2, represent hydrolyzable groups selected from alkoxy, acyloxy or halide groups; and
the R groups, which may be identical or different when n is equal to 2 or 3, represent non-hydrolyzable organic groups or organic functions bonded to the silicon via a carbon atom,
said metal oxide precursor(s) and said organosilane(s) having undergone a hydrolysis and a condensation during said curing.

4. The coated substrate as claimed in claim 3, wherein the metal oxide precursor is a precursor of an oxide of a metal selected from the group consisting of Si, Ti, Zr, Al, Zn, Sn, Nb, and Sb.

5. The coated substrate as claimed in claim 3, wherein the X groups are selected from the group consisting of —O—R′ alkoxy groups, with R′ representing a C₁-C₄ alkyl group, —O—C(O)R″ acyloxy groups, with R″ representing an alkyl radical; halides such; and combinations thereof.

6. The coated substrate as claimed in claim 3, wherein the R groups are selected from the group consisting of methyl, glycidyl and glycidoxypropyl groups.

7. The coated substrate as claimed in claim 1, wherein the pores represent 5% to 74% by volume of a porous layer of inorganic material M1.

8. The coated substrate as claimed in claim 1, wherein the pores are of spherical or ovoid shape.

9. The coated substrate as claimed in claim 1, wherein the inorganic material M2 is in the form of nanoparticles adsorbed at the surface of the pores of the inorganic material M1.

10. The coated substrate as claimed in claim 1, wherein the inorganic material M2 is in the form of a coating over an entire inner surface of the pores.

11. The coated substrate as claimed in claim 1, wherein the inorganic material M2 is derived from an inorganic phase that is dispersable in the form of nanoparticles in water and that is adsorbable at the surface of particles of a latex, referred to as base latex.

12. The coated substrate as claimed in claim 1, wherein the material M2 includes particles that are catalytic nanoparticles or luminescent particles.

13. The coated substrate as claimed in claim 1, wherein the material M2 is based on at least one metal oxide or on a vanadate containing lanthanide ions.

14. The coated substrate as claimed in claim 1, wherein the layer of material M1 has a thickness of from 50 nm to 5 μm, and wherein the pores that the layer of material M1 contains have a mean largest dimension of from 30 to 600 nm.

15. The coated substrate as claimed in claim 9, wherein the nanoparticles have a dimension of from 5 to 100 nm.

16. The coated substrate as claimed in claim 10, wherein the coating of the inner surface of the pores has a thickness of from 2 to 50 nm.

17. The coated substrate as claimed in claim 1, wherein the material M1 is derived from a hydrolyzed SiO₂ precursor and the material M2 is TiO₂, the porous layer being an antireflection layer with a low refractive index and that has a self-cleaning functionality.

18. The coated substrate as claimed in claim 1, comprising the stack of functional layers of which the at least one porous functional layer of inorganic material M1 having, at the surface of at least one portion of the pores thereof, the at least one inorganic material M2 different from M1 are part, the functional layer(s) other than the aforementioned porous functional layer(s) having been deposited by a liquid method or by sputtering, or by liquid pyrolysis.

19. A process for manufacturing a coated substrate as defined in claim 1, the process comprising depositing by a liquid method on a glass or ceramic or glass-ceramic substrate at least one layer of an aqueous mixture of inorganic material M1 precursor and of a composite aqueous latex, the particles of which each consist of an organic core having a material M2 at the surface, and heating until the organic cores and water present in the mixture of precursor and of composite latex are eliminated or substantially eliminated.

20. The process as claimed in claim 19, wherein, as inorganic material M1 precursor, a sol-gel solution of at least one metal oxide precursor and/or of at least one organosilane of general formula is used:
RₙSiX₄₋ₙ,
wherein:
n is equal to 0, 1, 2 or 3;
the X groups, which may be identical or different when n is equal to 0, 1 or 2, represent hydrolyzable groups selected from alkoxy, acyloxy or halide groups; and
the R groups, which may be identical or different when n is equal to 2 or 3, represent non-hydrolyzable organic groups or organic functions bonded to the silicon via a carbon atom,
the inorganic material M1 being obtained by curing said sol-gel solution, during which said metal oxide precursor(s) and said organosilane(s) undergo a hydrolysis and a condensation.

21. The process as claimed in claim 20, wherein the metal oxide precursor is a precursor of an oxide of a metal selected from the group consisting of Si, Ti, Zr, Al, Zn, Sn, Nb, and Sb.

22. The process as claimed in claim 20, wherein the X groups are selected from —O—R′ alkoxy groups, with R′ representing a C₁-C₄ alkyl group, —O—C(O)R″ acyloxy groups, with R″ representing an alkyl radical; halides; and combinations thereof.

23. The process as claimed in claim 20, wherein the R groups are selected from the group consisting of methyl, glycidyl and glycidoxypropyl groups.

24. The process as claimed in claim 22, wherein tetraethoxysilane (TEOS) is used as inorganic material M1 precursor.

25. The process as claimed in claim 19, wherein the composite aqueous latex is prepared by mixing a base latex obtained by aqueous emulsion polymerization of a polymer or copolymer P with a dispersion in water of nanoparticles of organic material M2 under heterocoagulation conditions, in order to obtain a nanocomposite latex, of which the polymer or copolymer P particles constituting said organic cores bear at the surface said nanoparticles of material M2.

26. The process as claimed in claim 19, wherein, in the case where the inorganic material M2 is in the form of a shell over an entire inner surface of the pores of a porous layer, the composite aqueous latex is prepared by mixing a base latex obtained by aqueous emulsion polymerization of a polymer or copolymer P with an inorganic material M2 precursor in solution, and by adjusting the reaction conditions so that a condensation reaction takes place over the entire surface of the particles of the base latex, forming a covering of said particles with the inorganic material M2.

27. The process as claimed in claim 25, wherein the polymer or copolymer P is selected from poly(methyl methacrylate), methyl methacrylate/butyl acrylate copolymers and polystyrene.

28. The process as claimed in claim 19, wherein the material M2 is based on at least one metal oxide, or on a vanadate containing lanthanide ions.

29. The process as claimed in claim 19, wherein the layer of mixture is deposited by spin coating.

30. The process as claimed in claim 19, wherein in order to form a stack of layers, at least one other functional layer is deposited by a liquid method or by sputtering, or by liquid pyrolysis, in the order desired for the stack of layers.

31. A process comprising manufacturing an element with a coated substrate as defined in claim 1 wherein the element is an element of an optoelectronic device, or of a single or multiple, monolithic or laminated glazing unit for buildings and transport vehicles.

32. A photovoltaic module comprising a coated substrate as defined in claim 1 as cover glass.

33. A light-emitting device comprising a coated substrate as defined in claim 1 as organic light-emitting diode.

34. A single or multiple, monolithic or laminated glazing unit for buildings and transport vehicles, comprising at least one coated substrate as defined in claim 1 as pane or sheet of glass of a multiple glazing unit.
